(19) United States
(12) Patent Application Publication
(10) Pub. No.: US 2023/0257314 A1
(43) Pub. Date: Aug. 17, 2023

(54) PLASMA RESISTANT CERAMIC MEMBER AND MANUFACTURING METHOD OF THE SAME

(71) Applicant: KOREA INSTITUTE OF CERAMIC ENGINEERING AND TECHNOLOGY, Jinju-si (KR)

(72) Inventors: Sung min LEE, Seoul (KR); Yoon Suk OH, Seoul (KR); Hyeong Jun KIM, Cheonan-si (KR); Gyusang OH, Geoje-si (KR)

(73) Assignee: KOREA INSTITUTE OF CERAMIC ENGINEERING AND TECHNOLOGY, Jinju-si (KR)

(21) Appl. No.: 17/980,287

(22) Filed: Nov. 3, 2022

(30) Foreign Application Priority Data
Nov. 19, 2021 (KR) 10-2021-0159928

(51) Int. Cl. C04B 41/52; C04B 35/10; C04B 41/50; C04B 41/45; C04B 41/00; C04B 41/87; C23C 4/11

(52) U.S. Cl. CPC C04B 41/522; C04B 35/10; C04B 41/5045; C04B 41/5055; C04B 41/4543; C04B 41/4558; C04B 41/0072; C04B 41/87; C23C 4/11; C04B 2235/3217; C04B 2235/9669

(57) ABSTRACT

The present invention provides a plasma-resistant ceramic member, which includes a substrate and a ceramic coating layer formed on the substrate, in which the ceramic coating layer includes a lower layer consisting of an oxide formed on the substrate, and a surface layer in which an oxide composition component constituting the surface of the ceramic coating layer is surface-modified with a composition containing one or more anions selected from the group consisting of F⁻ and Cl⁻, wherein the surface layer is a layer in which a raw material containing one or more anions selected from the group consisting of F⁻ and Cl⁻ is vaporized by heating and adsorbed to the surface of the ceramic coating layer, and thus modified with a composition containing one or more anions selected from the group consisting of F⁻ and Cl⁻, and a method of manufacturing the same. According to the present invention, the plasma-resistant property, durability, and etching process stability of the ceramic member may be improved with low costs.

### CROSS-REFERENCE TO RELATED APPLICATION

This application claims priority to and the benefit of Korean Patent Application No. 10-2021-0159928, filed on Nov. 19, 2021, the disclosure of which is incorporated herein by reference in its entirety.

### BACKGROUND

### 1. Field of the Invention

The present invention relates to a plasma-resistant ceramic member and a method of manufacturing the same, and more particularly, to a plasma-resistant ceramic member which can improve plasma resistance, durability and etching process stability by surface-modifying the surface of a ceramic coating layer coated on a substrate with a composition containing one or more anions selected from the group consisting of F⁻ and Cl⁻ using raw materials containing F or Cl and a low-cost thermal treatment technique providing raw materials by vaporization, and a method of manufacturing the same.

### 2. Discussion of Related Art

A plasma process not only promotes a chemical reaction with a material by generating a radical with high chemical activity, but also promotes a reaction by the incidence of ions dissociated by plasma on a material surface with high energy and causes physical etching of the material. A representative material having an excellent plasma resistant property may be Al₂O₃, and recently, yttrium oxide (Y₂O₃) or yttria-stabilized zirconia (YSZ), which has very excellent plasma resistance, has been adopted and being widely used. In recent years, the use of products coated with yttrium oxide on aluminum or aluminum oxide (alumina) by plasma spraying or PVD, rather than bulk products in which yttrium oxide or the like is sintered at high temperature, is expanding. Such coated products have the advantages of manufacturing a plasma-resistant member with low costs and having less risk of damage compared to bulk products manufactured using a sintering method.

When used as a part of semiconductor manufacturing equipment, a product in which Y₂O₃, YSZ (yttria stabilized zirconia), or zirconia doped with one or more elements from the group containing rare earth elements, Ca and Mg is coated on a substrate such as aluminum or alumina and is exposed to a vacuum plasma process environment containing an element (F or Cl) causing chemical deterioration of a ceramic coating layer. As described above, when the ceramic coating layer is deteriorated by exposure to the vacuum plasma process environment, contamination (particle-type or reactant-type) occurs during a semiconductor manufacturing process, and a cause of lowering the wafer production yield is provided. In addition, an increase in cost of post-processing for part recycling such as a cleaning process is caused.

For example, when Y₂O₃ is exposed to plasma, fluorine-containing contaminant particles are formed on a surface layer, and when Y₂O₃ is subjected to thermal cycling, due to the difference in thermal expansion coefficient between the contaminant particles on the surface layer and Y₂O₃, there is a problem in that stress is generated and the contaminant particles are dropped into equipment for the semiconductor manufacturing process. The dropped contaminant particles lower the yield of the product to cause a problem of reducing the wafer production yield. To prevent the drop-off of the surface contaminant particles, a method of forming a YOₓF_{y} coating layer having a high bonding strength between the surface particle and a substrate using plasma spraying or a PVD method has been used. However, to form a F-containing YOₓF_{y} coating layer by plasma spraying, a complicated and high-cost method with several steps is required. For example, a process of mixing a F-containing raw material in a desired composition, a process of preparing a 10- to 50-μm spherical granular powder through spheroidization of the synthesized raw material, a process of thermally treating the spherical granular powder, and a process of coating the spherical powder using a plasma sprayer are required. Nevertheless, since the coating layer formed by the above procedure uses high-temperature plasma for the melting of granules during coating, it is difficult for the coating layer to obtain a desired coating composition and there is also a problem of lowering the density of the coating layer due to oxidation of the coating layer or volatilized F. Since a conventional Y₂O₃ plasma spraying product is an oxide, granules can be easily prepared in the air without mixing, there is no loss caused by volatilization during thermal treatment, and during the plasma spraying process, there is no problem of composition change or decreased density caused by volatilization during plasma spraying, which are big differences from the present invention. Therefore, compared to Y₂O₃, there is a disadvantage in that it is not possible to easily manufacture a YOₓF_{y} coating layer that can sufficiently inhibit the generation of contaminant particles. The manufacture of the YOₓF_{y} coating layer using PVD also has a similar problem. For example, in the case of a typical PVD method, which is electron beam physical vapor deposition, a process of mixing an F-containing raw material, a process of forming it into a compact, a process of solidifying the compact through thermal treatment at room temperature, and a process of preparing an evaporation source by grinding the resulting product in a uniform size are required. Even in the preparation of an evaporation source, when the power of an electron beam is adjusted to control a deposition rate during the melting and deposition of the evaporation source with the electron beam, the evaporation rate of oxygen and fluorine fluctuates, so it is very difficult to constantly maintain the contents of oxygen and fluorine in the deposited coating layer.

### SUMMARY OF THE INVENTION

The present invention is directed to providing a plasma-resistant ceramic member which can improve plasma resistance, durability and etching process stability by surface-modifying the surface of a ceramic coating layer on a substrate using a F or Cl-containing vapors from a F or Cl-containing raw material and a low-cost vaporization and thermal treatment technique providing the material F- or Cl-modified surface of plasma resistant parts and a method of manufacturing the same.

The present invention provides a plasma-resistant ceramic member including a substrate, and a ceramic coating layer formed on the substrate, wherein the ceramic coating layer includes a lower layer consisting of an oxide formed on the substrate; and a surface layer in which an oxide composition component constituting the surface of the ceramic coating layer is surface-modified with a composition containing one or more anions selected from the group consisting of F⁻ and Cl⁻. The surface layer is a layer in which a raw material containing one or more anions selected from the group consisting of F⁻ and Cl⁻ is vaporized by heating and adsorbed to the surface of the ceramic coating layer, and thus modified with a composition containing one or more anions selected from the group consisting of F⁻ and Cl⁻.

The lower layer may consist of Y₂O₃, Y₃Al₅O₁₂, YSZ (yttria stabilized zirconia), or zirconia doped with one or more elements from the group containing rare earth elements, Ca and Mg.

The surface layer may have a thickness of 100 nm to 50 μm.

The raw material may include one or more solid materials selected from the group consisting of NH₄F, NH₅F₂, LiF, NaF, KF, MgF₂, CaF₂, AlF₃ and YF₃.

The raw materials may include one or more solid materials selected from the group consisting of NH₄Cl, YCl₃, AlCl₃ and TaCl₃.

The raw material may be a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

A non-reactive solid diluent may be further mixed with the raw material and heated together, and the amount of the raw material vaporized by heating may be adjusted by the non-reactive solid diluent.

The concentration of the vaporized raw material may be controlled or an atmosphere for surface modification may be controlled by inputting an inert carrier gas in a process of moving the vaporized raw material to the ceramic coating layer.

The oxygen content of the modified surface layer may be controlled by inputting air or oxygen (O₂) gas in the process of moving the vaporized raw material to the ceramic coating layer.

The surface layer may be formed by heating a ceramic coating layer to be surface-modified and a raw material containing one or more anions selected from the group consisting of F⁻ and Cl⁻, and adsorbing the raw material vaporized by heating to the surface of the heated ceramic coating layer and thus modifying the surface of the ceramic coating layer with a composition including one or more anions selected from the group consisting of F⁻ and Cl⁻.

The surface layer may be formed by heating the raw material to a temperature of 100 to 500° C. to vaporize the same and adsorbing the resultant to the surface of the ceramic coating layer.

In addition, the present invention provides a method of manufacturing a plasma-resistant ceramic member by (a) preparing a substrate on which a ceramic coating layer consisting of an oxide composition is formed, (b) heating and vaporizing a raw material containing one or more anions selected from the group consisting of F⁻ and Cl, and (c) forming a surface layer by adsorbing the vaporized raw material to the surface of the ceramic coating layer and modifying the surface of the ceramic coating layer, wherein the surface layer is a layer in which an oxide composition component is modified with a composition including one or more anions selected from the group consisting of F⁻ and Cl⁻.

The ceramic coating layer may consist of Y₂O₃, Y₃AlO₁₂, yttria-stabilized zirconia, or zirconia doped with one or more elements from the group containing rare earth elements, Ca and Mg.

The surface layer may be formed to a thickness of 100 nm to 50 μm.

The raw material may include one or more solid materials selected from the group consisting of NH₄F, NH₅F₂, LiF, NaF, KF, MgF₂, CaF₂, AlF₃ and YF₃.

The raw material may include one or more solid materials selected from the group consisting of NH₄Cl, YCl₃, AlCl₃ and TaCl₃.

The raw material may be a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

A non-reactive solid diluent may be further mixed with the raw material and heated together, and the amount of the raw material vaporized by heating may be adjusted by the non-reactive solid diluent.

The concentration of the vaporized raw material or an atmosphere for surface modification may be controlled by inputting an inert carrier gas in a process of moving the vaporized raw material to the ceramic coating layer.

In the process of moving the vaporized raw material to the ceramic coating layer, an oxygen content of the modified surface layer may be controlled by inputting an air or oxygen (O₂) gas.

The surface layer may be formed by modifying the surface of the ceramic coating surface with a composition including one or more anions selected from the group consisting of F⁻ and Cl⁻ by heating the ceramic coating layer to be surface-modified and the raw material containing one or more anions selected from the group consisting of F⁻ and Cl⁻ and adsorbing the raw material vaporized by heating to the surface of the ceramic coating layer.

It is preferable that the raw material is heated to 100 to 500° C. to vaporize the same, and the resultant is adsorbed to the surface of the ceramic coating layer.

Step (b) may include (d) putting the substrate on which a ceramic coating layer to be surface-modified is formed and the raw material containing one or more anions selected from the group consisting of F⁻ and Cl⁻ into a crucible; (e) loading the crucible in which the substrate having the ceramic coating layer and the raw material are contained into a chamber configured to adjust an inner temperature by a heating means; and (f) heating and vaporizing the raw material using the heating means.

Step (d) is preferably to put the substrate having the ceramic coating layer and the raw material into the crucible to be placed separately from each other.

Preferably, the substrate having the ceramic coating layer is placed higher than the raw material.

It is preferable that a support provided to be higher than the bottom surface of the crucible and smaller than the inner diameter thereof is included in the crucible, the raw material is placed on the bottom surface of the crucible, and the substrate having the ceramic coating layer is set on the support to be placed higher than the raw material, so that the raw material and the substrate having the ceramic coating layer are spatially separated.

Step (b) may include placing the substrate on which the ceramic coating layer to be surface modified is formed in a furnace, putting the raw material for surface modification in the crucible, and placing the crucible in the furnace so that the raw material is spaced apart from the substrate having the ceramic coating layer to be surface-modified, and heating and vaporizing the raw material using a heating means. Here, in the furnace, a heating temperature for the substrate having the ceramic coating layer and a heating temperature for the raw material may be set differently from each other.

The heating temperature for the raw material is preferably set lower than that for the substrate having the ceramic coating layer.

The substrate having the ceramic coating layer and the raw material may be heated using the heating means, and a carrier gas may be flowed to allow the vaporized raw material to move to the substrate to be adsorbed to the surface of the ceramic coating layer.

In addition, step (b) may include placing the substrate on which a ceramic coating layer to be surface-modified is formed in a first furnace, putting a raw material for surface modification in a crucible and placing the crucible in a second furnace, and heating and vaporizing the substrate having the ceramic coating layer using a first heating means and heating and vaporizing the raw material using a second heating means, wherein a heating temperature for the substrate having the ceramic coating layer and a heating temperature for the raw material may be set differently from each other.

It is preferable to set the heating temperature for the raw material lower than that of the substrate having the ceramic coating layer.

The substrate having the ceramic coating layer may be heated using the first heating means, the raw material may be heated using the second heating means, a carrier gas may be flowed to the second furnace to allow the vaporized raw material to be introduced into the first furnace, and the vaporized raw material introduced into the first furnace may move to the substrate to be adsorbed to the surface of the ceramic coating layer.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 shows a ceramic coating layer 20 and a substrate 10;

FIG. 2 and FIG. 3 show an example of a system for surface-modifying a ceramic coating layer;

FIG. 4 and FIG. 5 show another example of a system for surface-modifying a ceramic coating layer;

FIG. 6 shows a still another example of a system for surface-modifying a ceramic coating layer;

FIG. 7 shows a plasma-resistant ceramic member according to an exemplary embodiment of the present invention;

FIG. 8 is a scanning electron microscope (SEM) photograph showing the surface-modified cross-section of a Y₂O₃ coating layer according to Experimental Example 1;

FIG. 9 is an SEM photograph showing the surface-modified cross-section of a Y₂O₃ coating layer according to Experimental Example 2;

FIG. 10 shows the energy dispersive X-ray spectroscopy (EDX) line profile of the surface-modified Y₂O₃ coating layer according to Experimental Example 2;

FIG. 11 is an SEM photograph showing the surface of the surface-modified Y₂O₃ coating layer according to Experimental Example 2;

FIG. 12 is an SEM photograph showing the surface of the surface-modified Y₂O₃ coating layer according to Experimental Example 3; and

FIG. 13 is an SEM photograph showing the surface of the surface-modified Y₂O₃ coating layer according to Experimental Example 3.

### DETAILED DESCRIPTION OF EXEMPLARY EMBODIMENTS

Hereinafter, exemplary embodiments according to the present invention will be described in detail with reference to the accompanying drawings. However, the following embodiments are provided for full understanding of the present invention by those of ordinary skill in the art and can be modified into various forms, and the scope of the present invention is not limited to embodiments to be described below.

In the detailed description or claims of the present invention, when any one component “includes” another component, unless specifically stated otherwise, it should not be construed as being limited to consisting only of the component, and it should be understood that another component may be further included.

Hereinafter, the “lower layer” refers to a part constituting the inside of the surface-modified ceramic coating layer, excluding a surface layer.

A plasma-resistant ceramic member according to an exemplary embodiment of the present invention is a ceramic member including a substrate; and a ceramic coating layer formed on the substrate, wherein the ceramic coating layer includes a lower layer consisting of an oxide formed on the substrate; and a surface layer in which an oxide composition component constituting the surface of the ceramic coating layer is surface-modified with a composition containing one or more anions selected from the group consisting of F⁻ and Cl⁻; wherein the surface layer is a layer in which a raw material containing one or more anions selected from the group consisting of F⁻ and Cl⁻ is vaporized by heating and adsorbed to the surface of the ceramic coating layer, and thus modified with a composition containing one or more anions selected from the group consisting of F⁻ and Cl⁻.

The lower layer may consist of Y₂O₃, Y₃Al₅O₁₂, yttria-stabilized zirconia, or zirconia doped with one or more elements selected from rare earth elements, Ca and Mg.

The surface layer may have a thickness of 100 nm to 50 μm.

The raw material may include one or more solid materials selected from the group consisting of NH₄F, NH₅F₂, LiF, NaF, KF, MgF₂, CaF₂, AlF₃ and YF₃.

The raw materials may include one or more solid materials selected from the group consisting of NH₄Cl, YCl₃, AlCl₃ and TaCl₃.

The raw material may be a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

A non-reactive solid diluent may be further mixed with the raw material and heated together, and the amount of the raw material vaporized by heating may be adjusted by the non-reactive solid diluent.

The concentration of the vaporized raw material may be controlled or an atmosphere for surface modification may be controlled by inputting an inert carrier gas in a process of moving the vaporized raw material to the ceramic coating layer.

The oxygen content of the modified surface layer may be controlled by inputting air or oxygen (O₂) gas in the process of moving the vaporized raw material to the ceramic coating layer.

The surface layer may be formed by heating a ceramic coating layer to be surface-modified and a raw material containing one or more anions selected from the group consisting of F⁻ and Cl⁻, adsorbing the raw material vaporized by heating to the surface of the heated ceramic coating layer and thus modifying the surface of the ceramic coating layer with a composition including one or more anions selected from the group consisting of F⁻ and Cl⁻.

The surface layer may be formed by heating the raw material to a temperature of 100 to 500° C. to vaporize the same and adsorbing the resultant to the surface of the ceramic coating layer.

A method of manufacturing a plasma-resistant ceramic member according to an exemplary embodiment of the present invention includes (a) preparing a substrate on which a ceramic coating layer of an oxide composition is formed, (b) heating and vaporizing a raw material containing one or more anions selected from the group consisting of F⁻ and Cl⁻, and (c) forming a surface layer by adsorbing the vaporized raw material to the surface of the ceramic coating layer and modifying the surface of the ceramic coating layer, wherein the surface layer is a layer in which an oxide composition component is modified with a composition including one or more anions selected from the group consisting of F⁻ and Cl⁻.

The ceramic coating layer may consist of Y₂O₃, Y₃Al₅O₁₂, yttria-stabilized zirconia, or zirconia doped with one or more elements selected from rare earth elements, Ca and Mg.

The surface layer may be formed to a thickness of 100 nm to 50 μm.

The raw material may include one or more solid materials selected from the group consisting of NH₄F, NH₅F₂, LiF, NaF, KF, MgF₂, CaF₂, AlF₃ and YF₃.

The raw material may include one or more solid materials selected from the group consisting of NH₄Cl, YCl₃, AlCl₃ and TaCl₃.

The raw material may be a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

A non-reactive solid diluent may be further mixed with the raw material and heated together, and the amount of the raw material vaporized by heating may be adjusted by the non-reactive solid diluent.

The concentration of the vaporized raw material or an atmosphere for surface modification may be controlled by inputting an inert carrier gas in the process of moving the vaporized raw material to the ceramic coating layer.

In the process of moving the vaporized raw material to the ceramic coating layer, an oxygen content of the modified surface layer may be controlled by inputting air or oxygen (O₂) gas.

The surface layer may be formed by modifying the surface of the ceramic coating surface with a composition including one or more anions selected from the group consisting of F⁻ and Cl⁻ by heating the ceramic coating layer to be surface-modified and the raw material containing one or more anions selected from the group consisting of F⁻ and Cl⁻ and adsorbing the raw material vaporized by heating to the surface of the ceramic coating layer.

It is preferable that the raw material is heated to 100 to 500° C. to vaporize the same, and the resultant is adsorbed to the surface of the ceramic coating layer.

Step (b) may include (d) putting the substrate on which a ceramic coating layer to be surface-modified is formed and the raw material containing one or more anions selected from the group consisting of F⁻ and Cl⁻ into a crucible; (e) loading the crucible having the substrate having the ceramic coating layer and the raw material into a chamber configured to adjust an inner temperature by a heating means; and (f) heating and vaporizing the raw material using the heating means.

In step (d), it is preferable to put the substrate having the ceramic coating layer and the raw material into the crucible so as to be positioned separately from each other.

Preferably, the substrate having the ceramic coating layer is positioned higher than the raw material.

It is preferable that a support provided to be higher than the bottom surface of the crucible and smaller than the inner diameter thereof is included in the crucible, and the raw material is placed on the bottom surface of the crucible, the substrate having the ceramic coating layer is mounted on the support to be positioned higher than the raw material, so that the raw material and the substrate having the ceramic coating layer are spatially separated.

Step (b) may include placing the substrate on which the ceramic coating layer to be surface modified is formed in a furnace, putting the raw material for surface modification in the crucible, and placing the crucible in the furnace so that the raw material is spaced apart from the substrate having the ceramic coating layer to be surface-modified, and heating and vaporizing the raw material using a heating means, wherein a heating temperature for the substrate having the ceramic coating layer and a heating temperature for the raw material may be set differently from each other in the furnace.

The heating temperature for the raw material is preferably set lower than that for the substrate having the ceramic coating layer.

The substrate having the ceramic coating layer and the raw material may be heated using the heating means, and a carrier gas may be flowed to allow the vaporized raw material to move to the substrate to be adsorbed to the surface of the ceramic coating layer.

In addition, step (b) may include placing the substrate on which a ceramic coating layer to be surface-modified is formed in a first furnace, putting a raw material for surface modification in a crucible and placing the crucible in a second furnace, and heating and vaporizing the substrate having the ceramic coating layer using a first heating means and heating and vaporizing the raw material using a second heating means, wherein a heating temperature for the substrate having the ceramic coating layer and a heating temperature for the raw material may be set differently from each other.

It is preferable to set a heating temperature for the raw material lower than that of the substrate having the ceramic coating layer.

The substrate having the ceramic coating layer may be heated using the first heating means, the raw material may be heated using the second heating means, a carrier gas may be flowed to the second furnace to allow the vaporized raw material to be introduced into the first furnace, and the vaporized raw material introduced into the first furnace may move to the substrate to be adsorbed to the surface of the ceramic coating layer.

Hereinafter, the plasma-resistant ceramic member according to an exemplary embodiment of the present invention will be described in further detail.

When used as a part of semiconductor manufacturing equipment, a product in which Y₂O₃, Y₃Al₅O₁₂, yttria-stabilized zirconia, or zirconia doped with one or more elements selected from rare earth elements, Ca and Mg is coated on a substrate such as aluminum or alumina is exposed to a vacuum plasma process environment containing an element (F or Cl) causing chemical deterioration of a ceramic coating layer. As described above, when the ceramic coating layer is deteriorated by exposure to the vacuum plasma process environment, contamination (particle-type or reactant-type) occurs during a semiconductor manufacturing process, and a cause of lowering the wafer production yield is provided. In addition, an increase in cost of post-processing for part recycling such as a cleaning process is caused.

The inventors of the present invention are studying a technique for applying a coating with a composition of an F-based material such as a fluoride or oxyfluoride, for example, YF₃ or YOₓF_{y} to reduce the deterioration of an oxide part by a plasma process to the surface of a ceramic substrate, and are conducting research on better coating technology and materials.

Conventionally, to obtain a composition containing F for improvement in plasma resistance, a process of mixing a F-containing raw material in a desired composition, a process of preparing a 10- to 50-μm spherical granular powder through spheroidization of the synthesized raw material, a process of thermally treating the spherical granular powder, and a process of coating the spherical powder using a plasma sprayer are required. Nevertheless, since the coating layer formed through the above procedures uses a high-temperature plasma to melt granules during coating, it is difficult to obtain a desired coating composition due to oxidation of the coating layer or volatilization of F, and there is also a problem of a decreased density of the coating layer.

The present invention provides a plasma-resistant ceramic member in which plasma resistance and durability are strengthened through the surface modification of a ceramic oxide part applied to semiconductor chip production process equipment (etching or CVD coating). The surface of a ceramic coating layer (oxide coating layer) coated on a substrate may be modified using a low-cost thermal treatment technique using a F or Cl⁻ containing raw material (salt), and thus plasma resistance, durability and etching process stability may be improved.

FIG. 7 shows the plasma-resistant ceramic member according to the exemplary embodiment of the present invention.

Referring to FIG. 7, the plasma-resistant ceramic member according to the exemplary embodiment of the present invention is a ceramic member which includes a substrate 10 and a ceramic coating layer formed on the substrate 10, wherein the ceramic coating layer includes a lower layer 20a consisting of an oxide formed on the substrate, and a surface layer (upper layer) 20b in which an oxide composition component constituting the surface of the ceramic coating layer is surface-modified with a composition containing one or more anions selected from the group consisting of F⁻ and Cl⁻.

The substrate 10 may be a metal substrate such as an aluminum substrate or a ceramic substrate, but the present invention is not limited thereto. The ceramic substrate may consist of a material containing alumina (Al₂O₃) as a main ingredient, but the present invention is not limited thereto.

In the case of a ceramic with a stable crystal structure such as alumina, since it is difficult to form a composite anionic composition (—OF, —OCl, or —FCl) due to diffusion or substitution of an anion, an oxide-based ceramic which enables relatively free diffusion or substitution of an anionic element such as F⁻ or Cl⁻ is used. The lower layer 20a may consist of a Y₂O₃, Y₃Al₅O₁₂, yttria-stabilized zirconia, or zirconia doped with one or more elements selected from rare earth elements, Ca and Mg. The rare earth elements may include La, Ce, Pr, Nd, Pm, Sm, Eu, Gd, Tb, Dy, Ho, Er, Tm, and Yb.

Since yttria (Y₂O₃) has excellent chemical stability and heat resistance, it is widely used not only for plasma resistance, but also for a high-temperature corrosion-resistant engine material, a molten metal nozzle material for jet-casting, and a container material for melting a metal with very high reactivity, such as lithium or uranium.

Zirconia (ZrO₂) has a molecular weight of approximately 123.22, a melting point of approximately 2,700° C., a high refractive index, and high corrosion resistance due to a high melting point. Among various ceramic materials, zirconia (zirconium oxide (ZrO₂)) has the advantages of the lowest thermal conductivity, high thermal stability, and a very large coefficient of thermal expansion. However, pure zirconia has a phase transformation characteristic of monoclinic↔tetragonal↔cubic crystal accompanied by a volume change according to a temperature change. Such volume change during phase transformation is a major factor in the deterioration of zirconia. To overcome the phase transformation problem, zirconia is stabilized by adding a ceramic such as yttria (Y₂O₃), magnesia (MgO), calcia (CaO), or ceria (CeO₂) (refers to stabilized zirconia). Particularly, zirconia stabilized by adding yttria (Y₂O₃) is called yttria-stabilized zirconia (YSZ). As described above, in zirconia (ZrO₂), volume expansion occurs during a phase transition from a tetragonal phase to a monoclinic phase, and when such volume expansion occurs, zirconia becomes weak against heat shock. Therefore, to solve the problem of weakening against heat shock, stabilized zirconia is prepared by adding an oxide such as yttria (Y₂O₃).

The surface layer (upper layer) 20b is a layer in which a raw material containing one or more anions selected from the group consisting of F⁻ and Cl⁻ (raw material containing one or more elements selected from the group consisting of F and Cl) is vaporized by heating, adsorbed to the surface of the ceramic coating layer, and thus modified with a composition containing one or more anions selected from the group consisting of F⁻ and Cl⁻.

The ceramic coating layer to be surface modified and the raw material containing one or more anions selected from the group consisting of F⁻ and Cl⁻ (raw material containing one or more elements selected from the group consisting of F and Cl) may be heated, the raw material vaporized by heating may be adsorbed to the surface of the ceramic coating layer to modify the surface of the ceramic coating layer with a composition containing one or more anions selected from the group consisting of F⁻ and Cl⁻, thereby forming the surface layer. The part in which the raw material containing one or more anions selected from the group consisting of F⁻ and Cl⁻ is heated and the substrate on which the ceramic coating layer to be surface modified is formed may be spatially separated and heated. Such spatial separation has the advantage of individually adjusting a temperature of the ceramic coating layer to be surface modified and a temperature for heating the raw material and the advantage of securing the means for controlling the composition of the surface layer or the rate of generating the surface layer by separately inputting a carrier gas of the controlled composition transporting a gas phase. In addition, when the gas phase is activated by placing a plasma generator on the gas phase moving path that enables surface modification, a method of increasing the rate of surface modification may be included.

The surface layer may be formed by vaporizing the raw material by heating to 100 to 500° C. and adsorbing the resultant to the surface of the ceramic coating layer.

The raw material may be a material containing one or more selected from the group consisting of F and Cl, and more specifically, a material containing one or more anions selected from the group consisting of F⁻ and Cl⁻. The raw material may include one or more solid materials selected from the group consisting of NH₄F, NH₅F₂, LiF, NaF, KF, MgF₂, CaF₂, AlF₃ and YF₃. The raw material may include one or more solid materials selected from the group consisting of NH₄Cl, YCl₃, AlCl₃ and TaCl₃. The raw material may be a slid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

As a raw material for modifying the surface of the ceramic coating layer, a raw material containing an anion with high reactivity such as F⁻ or Cl⁻ (e.g., NH₄F) is used. Examples of raw materials containing an F⁻ ion with high reactivity may include NH₄F, NH₅F₂, LiF, NaF, KF, MgF₂, CaF₂, AlF₃, YF₃, and a mixture thereof. Examples of raw materials containing an Cl⁻ ion with high reactivity may include NH₄Cl, YCl₃, AlCl₃, TaCl₃, or a mixture thereof. Two or more types of the raw materials may be used, and to adjust a volatilization level, a solid low-reactivity diluent may be added. For example, a mixture of NH₄F and LiF containing an F⁻ ion with high reactivity may be used. A mixture of a raw material containing an F⁻ ion with high reactivity and a raw material containing a Cl⁻ ion with high reactivity may also be used.

A non-reactive solid diluent may be further mixed to the raw material and heated together with the raw material, and the amount of the raw material vaporized by heating may be adjusted by the non-reactive solid diluent. The non-reactive solid diluent is a non-reactive material that is not vaporized even by the thermal treatment (heating), and an example thereof may be Al₂O₃. The non-reactive solid diluent is preferably mixed at 10 to 70 parts by weight with respect to 100 parts by weight of the raw material.

In addition, the concentration of the vaporized raw material may be controlled or an atmosphere for surface modification may be controlled by inputting an inert carrier gas in process of moving the vaporized raw material to the ceramic coating layer. As the inert carrier gas, a gas such as argon (Ar) or nitrogen (N₂) may be used. The inert carrier gas is preferably input at a flow rate of approximately 1 to 100 sccm.

In addition, the oxygen content of the modified surface layer may be controlled by inputting air or oxygen (O₂) gas in the process of moving the vaporized raw material to the ceramic coating layer. The air or oxygen (O₂) gas may be input along with the inert carrier gas. The air or oxygen (O₂) gas is preferably input at a flow rate of approximately 0.1 to 100 sccm.

The raw material is heated and vaporized, the vaporized raw material is adsorbed to the surface of a ceramic coating layer, thereby forming a surface layer on the ceramic coating layer. The surface of the ceramic coating layer may be modified by thermal treatment (heating) using a raw material containing an anion. The raw material is vaporized by thermal treatment (heating), and the vaporized raw material is adsorbed to the surface of the ceramic coating layer, leading to surface modification. The thermal treatment (heating) is preferably performed in an inert gas (unreactive gas) atmosphere such as argon, helium or nitrogen or a sealed condition at a temperature of approximately 100 to 500° C. To adjust an O/F ratio of the surface layer, oxygen may be further provided to the inert gas (unreactive gas) atmosphere to adjust the gas atmosphere. Through the thermal treatment (heating), an anionic element such as F⁻ or Cl⁻ may intrude into the ceramic coating layer to achieve surface modification on the surface of the ceramic coating layer, and by the surface modification, the plasma resistance and durability of the ceramic coating layer may be strengthened. The raw material and the ceramic coating layer is heated and vaporized by a heating means, the vaporized raw material is adsorbed to the surface of the ceramic coating layer to intrude into the surface of the ceramic coating layer, and surface modification occurs on the surface of the ceramic coating layer while substituted with elements constituting the surface of the ceramic coating layer (substitution-type diffusion) or intruding in-between the sites of elements constituting the surface of the ceramic coating layer (invasion or interstitial-type diffusion), thereby forming a surface layer on the surface of the ceramic coating layer. When the surface is modified using a raw material containing an F⁻ ion with high reactivity, a surface layer containing the F element is formed on the surface of the ceramic coating layer, and when the surface is modified using a raw material containing a Cl⁻ ion with high reactivity, a surface layer containing the Cl element is formed on the surface of the ceramic coating layer. When the raw material containing an F− ion with high reactivity and the raw material containing a Cl− ion with high reactivity are used together, a surface layer containing the F element and the Cl element is formed on the surface of the ceramic coating layer. In one example, when the surface of the ceramic coating layer, which is an yttria (Y₂O₃) coating layer, is modified according to the present invention, through thermal treatment using NH₄F as a surface modification raw material, the surface of the yttria (Y₂O₃) coating layer is modified with YOₓF_{y} (here, x is a positive real number of 1.5 or less, and y is a positive real number of 3 or less). In another example, when the surface of the ceramic coating layer, which is an yttria (Y₂O₃) coating layer, is modified according to the present invention, through thermal treatment using NH₄Cl as a surface modification raw material, the surface of the yttria (Y₂O₃) coating layer is modified with YOₓCl_{y} (here, x is a positive real number of 1.5 or less, and y is a positive real number of 3 or less).

The thermal treatment may be performed for 10 minutes to 48 hours, more preferably, for approximately 1 to 24 hours, and most preferably, for 2 to 12 hours. When the thermal treatment time is too long, it is not economical because it consumes a lot of energy, and as surface modification with a sufficient thickness was acquired, it is difficult to expect a further surface modification effect. When the thermal treatment time is short, it may be difficult to expect a desired plasma resistance characteristic due to incomplete surface modification. For the thermal treatment, a temperature may be increased to the thermal treatment temperature at a predetermined temperature increase rate (e.g., 1 to 50° C./min) and may be maintained for a predetermined time (e.g., approximately 10 minutes to 48 hours), and then the temperature may be lowered and the surface-modified result (thermally-treated result) may be unloaded.

The thickness of the surface layer formed on the surface of the ceramic coating layer (the surface-modified thickness on the surface of the ceramic coating layer) is preferably approximately 100 nm to 50 μm. The thickness of the surface layer may be adjusted by controlling a raw material used, a thermal treatment temperature, a thermal treatment time, a surface modification time, an amount of a carrier gas, and whether there is an activation process for a volatile material. The composition of the surface layer may also be adjusted by controlling a raw material used, a thermal treatment temperature, and the composition of a carrier gas.

Hereinafter, a method of manufacturing a plasma-resistant ceramic member according to an exemplary embodiment of the present invention will be described in further detail.

When a product manufactured by coating a substrate such as aluminum or alumina with Y₂O₃, Y₃Al₅O₁₂, yttria-stabilized zirconia, or zirconia doped with one or more elements selected from rare earth elements, Ca and Mg is applied as a part of semiconductor manufacturing equipment, it is exposed to a vacuum plasma process environment containing an element (F or Cl) causing chemical deterioration of the ceramic coating layer. In this way, when the ceramic coating layer is deteriorated by exposing to the vacuum plasma process environment, it appears in a contaminated form (particle-type, reactant-type) in the semiconductor manufacturing process, and provides a cause for lowering the wafer production yield. In addition, it causes an increase in the cost of a post-process for part recycling such as a cleaning process.

The inventors of the present invention are studying a technique for applying coating with a composition of an F-based material such as a fluoride or oxyfluoride, for example, YF₃ or YOₓF_{y} to reduce the deterioration of oxide parts by a plasma process to the surface of a ceramic substrate, and conducting research on better coating technology and materials.

The present invention provides a method of manufacturing a plasma-resistant ceramic member, which can strengthen plasma resistance and durability through the surface modification of ceramic oxide parts applied to equipment for a semiconductor chip production process (etching or CVD coating). The surface of a ceramic coating layer (oxide coating layer) coated on a substrate may be modified by a low-cost thermal treatment technique using a raw material (salt) containing F or Cl, and thereby plasma resistance, durability and etching process stability may be improved.

The present invention uses a raw material (e.g., NH₄F) containing an anion with high reactivity such as F⁻ or Cl⁻ to modify the surface of the ceramic coating layer at a low temperature of 500° C. or less through a low-cost thermal treatment technique. Compared to the overlay-type coating technique requiring an expensive coating device and a raw material, the method of the present invention using a low-cost raw material and a low-cost thermal treatment processing technique providing the raw material after vaporization can be suggested as a surface modification technique exhibiting the same or higher plasma resistance.

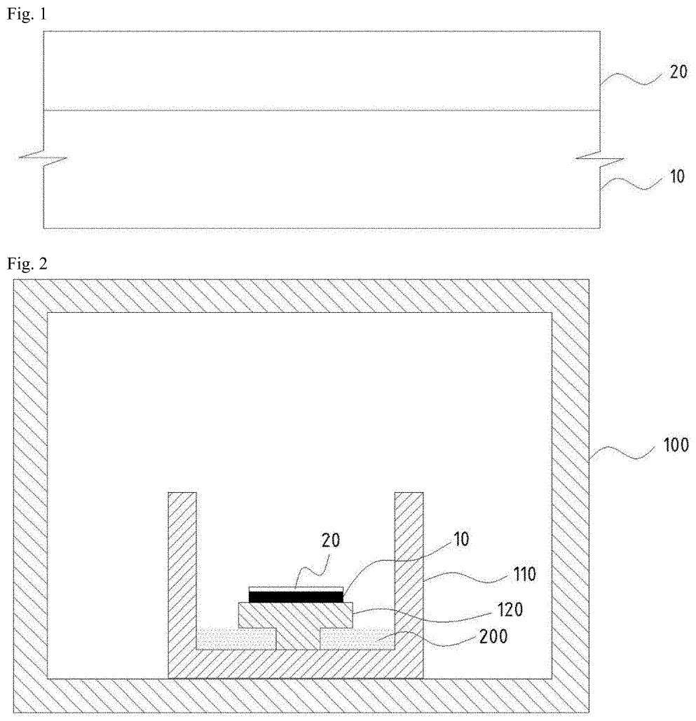

To manufacture a plasma-resistant ceramic member, a substrate 10 on which a ceramic coating layer 20 of an oxide composition is formed is prepared. FIG. 1 shows a ceramic coating layer 20 and a substrate 10.

The substrate 10 may be a metal substrate such as aluminum or a ceramic substrate, but the present invention is not limited thereto. The ceramic substrate may consist of a material containing alumina (Al₂O₃) as a main ingredient, but the present invention is not limited thereto.

In the case of a ceramic with a stable crystal structure such as alumina, it is difficult to form a composite anionic composition (—OF, —OCl, or —FCl) due to invasion or substitution of an anion, an oxide-based ceramic which enables relatively free invasion or substitution of an anionic element such as F⁻ or Cl⁻ is used.

Taking this into account, the ceramic coating layer 20 may consist of Y₂O₃, Y₃Al₅O₁₂, yttria-stabilized zirconia, or zirconia doped with one or more elements selected from rare earth elements (La, Ce, Pr, Nd, Pm, Sm, Eu, Gd, Tb, Dy, Ho, Er, Tm, Yb, etc.), Ca and Mg. The ceramic coating layer may be formed by a method such as plasma spray coating, chemical vapor deposition (CVD) coating, or physical vapor deposition (PVD) coating.

Since yttria (Y₂O₃) has excellent chemical stability and heat resistance, it is widely used for a high-temperature corrosion-resistant engine material, a molten metal nozzle material for jet-casting, and a container material for melting a metal with very high reactivity, such as lithium or uranium.

Zirconia (ZrO₂) has a molecular weight of approximately 123.22, a melting point of approximately 2,700° C., a high refractive index, and high corrosion resistance due to a high melting point. Among various ceramic materials, zirconia (zirconium oxide (ZrO₂)) has the advantages of the lowest thermal conductivity, high thermal stability, and a very large coefficient of thermal expansion. However, pure zirconia has a phase transformation characteristic of monoclinic↔tetragonal↔cubic crystals accompanied by a volume change according to a temperature change. Such volume change during phase transformation is a major factor in the deterioration of zirconia. To overcome the phase transformation problem, zirconia is stabilized by adding a ceramic such as yttria (Y₂O₃), magnesia (MgO), calcia (CaO), or ceria (CeO₂) (refers to stabilized zirconia). Particularly, zirconia stabilized by adding yttria (Y₂O₃) is called yttria-stabilized zirconia (YSZ). As described above, in zirconia (ZrO₂), volume expansion occurs during a phase transition from a tetragonal phase to a monoclinic phase, and when such volume expansion occurs, zirconia becomes weak against heat shock. Therefore, to solve the problem of weakening against heat shock, stabilized zirconia is prepared by adding an oxide such as yttria (Y₂O₃).

The thickness of the ceramic coating layer 20 may be approximately 200 nm to 150 μm.

A raw material is prepared. The raw material may be a material containing one or more elements selected from the group consisting of F and Cl, and more specifically, a material containing one or more anions selected from the group consisting of F⁻ and Cl⁻. The raw material may be a solid raw material containing one or more anions selected from the group consisting of F⁻ and Cl⁻. The raw material may include one or more solid materials selected from the group consisting of NH₄F, NH₅F₂, LiF, NaF, KF, MgF₂, CaF₂, AlF₃ and YF₃. The raw material may include one or more solid materials selected from the group consisting of NH₄Cl, YCl₃, AlCl₃ and TaCl₃. The raw material may be a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

As a raw material for modifying the surface of the ceramic coating layer, a raw material containing an anion with high reactivity such as F⁻ or Cl⁻ (e.g., NH₄F) is used. Examples of raw materials containing an F⁻ ion with high reactivity may include NH₄F, NH₅F₂, LiF, NaF, KF, MgF₂, CaF₂, AlF₃, YF₃, and a mixture thereof. Examples of raw materials containing an Cl⁻ ion with high reactivity may include NH₄Cl, YCl₃, AlCl₃, TaCl₃, or a mixture thereof. Two or more types of the raw materials may be used, and to adjust a volatilization level, a solid low-reactivity diluent may be added. For example, a mixture of NH₄F and LiF containing an F⁻ ion with high reactivity may be used. A mixture of a raw material containing an F⁻ ion with high reactivity and a raw material containing a Cl⁻ ion with high reactivity may also be used.

The method of manufacturing a plasma-resistant substrate according to an exemplary embodiment of the present invention includes heating and vaporizing a raw material containing one or more anions selected from the group consisting of F⁻ and Cl⁻, and forming a surface layer by adsorbing the vaporized raw material to the surface of the ceramic coating layer and modifying the surface of the ceramic coating layer. The surface layer is a layer in which the component of an oxide composition is modified with a composition containing one or more anions selected from the group consisting of F⁻ and Cl⁻.

The surface layer may be formed by modifying the surface of the ceramic coating surface with a composition including one or more anions selected from the group consisting of F⁻ and Cl⁻ by heating the ceramic coating layer to be surface-modified and the raw material containing one or more anions selected from the group consisting of F⁻ and Cl⁻ and adsorbing the raw material vaporized by heating to the surface of the ceramic coating layer.

The surface of the ceramic coating layer may be modified by thermal treatment (heating) using a raw material containing an anion. The raw material is vaporized by thermal treatment (heating), and the vaporized raw material is adsorbed to the surface of the ceramic coating layer, leading to surface modification. The thermal treatment (heating) is preferably performed in an inert gas (unreactive gas) atmosphere such as argon, helium or nitrogen or a sealed condition at a temperature of approximately 100 to 500° C. To adjust an O/F ratio of the surface layer, oxygen may be further provided to the inert gas (unreactive gas) atmosphere to adjust the gas atmosphere. Through the thermal treatment (heating), an anionic element such as F⁻ or Cl⁻ may intrude into the ceramic coating layer to achieve surface modification on the surface of the ceramic coating layer, and by the surface modification, the plasma resistance and durability of the ceramic coating layer may be strengthened. The raw material and the ceramic coating layer is heated and vaporized by a heating means, the vaporized raw material is adsorbed to the surface of the ceramic coating layer to intrude into the surface of the ceramic coating layer, and surface modification occurs on the surface of the ceramic coating layer while substituted with elements constituting the surface of the ceramic coating layer (substitution-type diffusion) or intruding between the sites of elements constituting the surface of the ceramic coating layer (invasion or interstitial-type diffusion), thereby forming a surface layer on the surface of the ceramic coating layer. When the surface is modified using a raw material containing an F⁻ ion with high reactivity, a surface layer containing the F element is formed on the surface of the ceramic coating layer, and when the surface is modified using a raw material containing a Cl⁻ ion with high reactivity, a surface layer containing the Cl element is formed on the surface of the ceramic coating layer. When the raw material containing an F⁻ ion with high reactivity and the raw material containing a Cl⁻ ion with high reactivity are used together, a surface layer containing the F element and the Cl element is formed on the surface of the ceramic coating layer. In one example, when the surface of the ceramic coating layer, which is an yttria (Y₂O₃) coating layer, is modified according to the present invention, through thermal treatment using NH₄F as the surface modification raw material, the surface of the yttria (Y₂O₃) coating layer is modified with YOₓF_{y} (here, x is a positive real number of 1.5 or less, and y is a positive real number of 3 or less). In another example, when the surface of the ceramic coating layer, which is an yttria (Y₂O₃) coating layer, is modified according to the present invention, through thermal treatment using NH₄Cl as the surface modification raw material, the surface of the yttria (Y₂O₃) coating layer is modified with YOₓCl_{y} (here, x is a positive real number of 1.5 or less, and y is a positive real number of 3 or less).

The thermal treatment may be performed for 10 minutes to 48 hours, more preferably, for approximately 1 to 24 hours, and most preferably, for 2 to 12 hours. When the thermal treatment time is too long, it is not economical because it consumes a lot of energy, and as surface modification with a sufficient thickness was acquired, it is difficult to expect a further surface modification effect. When the thermal treatment time is short, it may be difficult to expect a desired plasma resistance characteristic due to incomplete surface modification. For the thermal treatment. a temperature may be increased to the thermal treatment temperature at a predetermined temperature increase rate (e.g., 1 to 50° C./min) and may be maintained for a predetermined time (e.g., approximately 10 minutes to 48 hours), and then the temperature may be lowered and the surface-modified result (thermally-treated result) may be unloaded.

A non-reactive solid diluent may be further mixed with the raw material and heated together, and the amount of the raw material vaporized by heating may be adjusted by the non-reactive solid diluent. The non-reactive solid diluent is a non-reactive material that is not vaporized even by the thermal treatment (heating), and an example thereof may be Al₂O₃. The non-reactive solid diluent is preferably mixed at 0.1 to 100 parts by weight with respect to 100 parts by weight of the raw material.

In addition, the concentration of the vaporized raw material or an atmosphere for surface modification may be controlled by inputting an inert carrier gas in the process of moving the vaporized raw material to the ceramic coating layer. As the inert carrier gas, a gas such as argon (Ar) or nitrogen (N₂) may be used. The inert carrier gas is preferably input at a flow rate of approximately 0.01 to 2.0 sccm.

In addition, an oxygen content of the modified surface layer may be controlled by adding air or oxygen (O₂) gas in the process of moving the vaporized raw material to the ceramic coating layer. The air or oxygen (O₂) gas may be input along with the inert carrier gas. The air or oxygen (O₂) gas is preferably input at a flow rate of approximately 0.11 to 100 sccm.

The thickness of the surface layer formed on the surface of the ceramic coating layer (the surface-modified thickness on the surface of the ceramic coating layer) is preferably approximately 100 nm to 50 μm. The thickness of the surface layer may be adjusted by controlling a raw material used, a thermal treatment temperature, a thermal treatment time, a surface modification time, an amount of a carrier gas, and whether there is an activation process for a volatile material. The composition of the surface layer may also be adjusted by controlling a raw material used, a thermal treatment temperature, and the composition of a carrier gas.

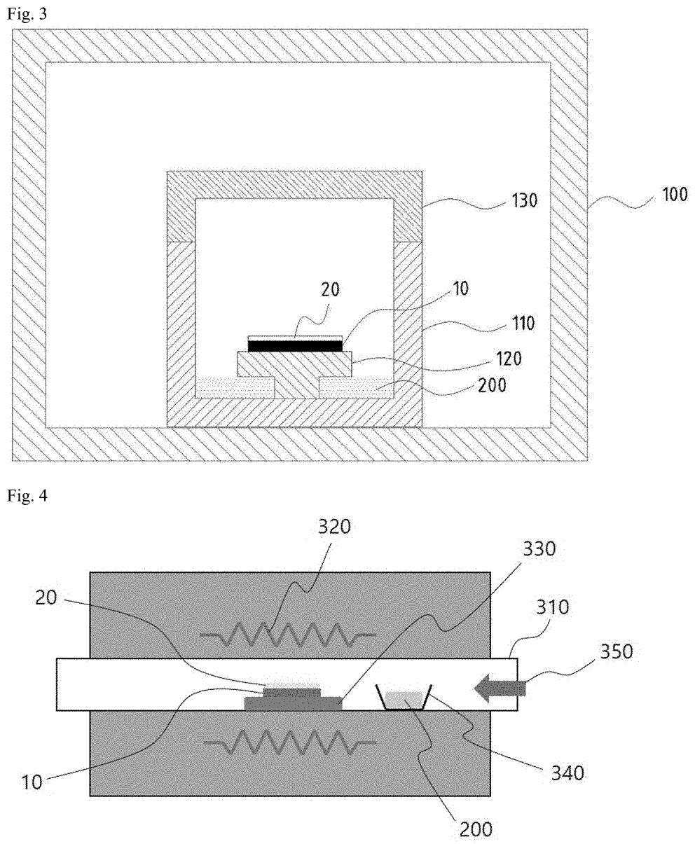

FIGS. 2 and 3 show an example of a system for surface-modifying a ceramic coating layer.

Referring to FIGS. 2 and 3, the system for surface-modifying a ceramic coating layer includes a chamber 100 configured to adjust an inner temperature through a heating means, a crucible 110 accommodated in the chamber 100, a substrate (oxide part) 10 accommodated in the crucible 110 and having a ceramic coating layer 20 to be surface-modified, and a raw material 200 accommodated in the crucible 110 for surface modification of the ceramic coating layer. The raw material 200 is a material containing one or more anions selected from the group consisting of F⁻ and Cl⁻.

The substrate having the ceramic coating layer 10 and the raw material 200 are contained in the crucible 110 in a predetermined volume ratio (e.g., substrate:raw material=1:0.1 to 1:50). It is preferable to place the substrate 10 and the raw material 200 in the crucible 110 to be positioned separately from each other. The crucible 110 preferably consists of a material with high hardness and a high melting point, such as alumina (Al₂O₃), graphite, carbon (carbon excluding graphite), tungsten or tantalum, and when the crucible 110 formed of a material having a low melting point is used, the crucible material may act as an impurity in a subsequent thermal treatment process. It is also possible to separate the substrate having the ceramic coating layer to be surface-modified and the raw material in separate places, and for example, the raw material is put into the crucible, each of the raw material-containing crucible and the substrate is loaded into the chamber to spatially separate the substrate from the raw material, and in this case, the substrate is positioned outside the crucible.

As shown in FIG. 3, the crucible 110 may further include a cover 130 for covering an upper part. The crucible 110 may have a structure to be sealed by the cover 130.

The system for surface-modifying a ceramic coating layer may further include a support 120 provided to be higher than the bottom surface of the crucible 110 and smaller than the inner diameter thereof, and the substrate 10 mounted on the support 120 is preferably positioned higher than the raw material 200. The support 120 is placed on the bottom surface of the crucible 110, the substrate 10 having the ceramic coating layer to be surface-modified is put on the support, and a raw material 200 containing an anion with high reactivity is put on the bottom surface of the crucible 110. The position at which the substrate 10 is mounted may be adjusted by adjusting the height of the support 120. As such, the support 120 may be used to spatially separate the raw material and the substrate.

The position of the substrate 10 having the ceramic coating layer to be surface-modified may be determined by adjusting the thickness (or height) of the support 120. In order to adjust the position of the substrate 10 having the ceramic coating layer to be surface-modified, the thickness (or height) of the support 120 may vary. For example, when the support 120 has a large thickness (or height), compared to when having a smaller thickness (or height), the substrate 10 is positioned toward the upper side of the crucible 110.

The crucible 110 having the substrate 10 and the raw material 200 is loaded into the chamber 100 configured to adjust an inner temperature by a heating means. The chamber 100 is set to adjust a temperature by a heating means (not shown).

The chamber 100 is preferably formed of a heat-resistant material (e.g., an alumina (Al₂O₃) material) which is chemically stable and has a higher melting point than the thermal treatment temperature. The heating means is configured to surround the chamber 100 and serves to heat the raw material 200 and the substrate 10 having the ceramic coating layer. The heating means serves to increase the inner temperature of the chamber 100 to a target temperature (e.g., 100 to 500° C.) and keep it constant. The heating means may use a method, such as resistance heating by a heating element or high frequency induction heating. The temperature in the chamber 100 may be constantly maintained by the heating means.

A gas inlet (not shown) through which a gas is input may be provided in the chamber 100. A gas such as a carrier gas or air may be input into the chamber 100 through the gas inlet.

A gas outlet (not shown) may be provided in the chamber 100, and an exhaust system (not shown) such as a pump may be installed at the gas outlet, and the gas remaining in the chamber 100 may be discharged to the outside after thermal treatment.

A cooling cylinder (not shown) may be provided around the chamber 100, and may be water-cooled by cooling water (CW) flowing inside the cooling cylinder to prevent overheating of the inside of the chamber 100 and rapidly cool the inside of the chamber 100. A cooling water inlet (CWI) is connected to the cooling cylinder to provide cooling water, the provided cooling water is discharged through a cooling water outlet (CWO), and it is preferable to allow the cooling water to circulate in the cooling cylinder so that the chamber 100 can be cooled uniformly as a whole.

The ceramic coating layer may be surface-modified by adsorbing the raw material 200 heated and vaporized by the heating means to the surface of the ceramic coating layer. A surface layer (upper layer) is formed by the surface modification, and the surface layer is a layer in which an oxide composition component is modified with a composition containing one or more anions selected from the group consisting of F⁻ and Cl⁻. The thickness of the surface-modified ceramic coating layer (the thickness of the lower layer and the surface layer) is the same as that of the ceramic coating layer before surface modification, or is larger due to volume expansion of the surface layer in the surface modification.

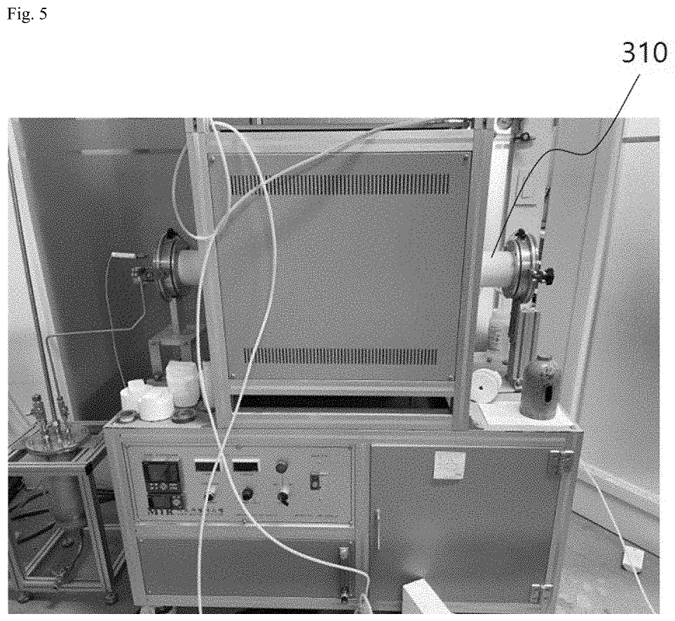

FIGS. 4 and 5 show another example of a system for surface-modifying a ceramic coating layer.

Referring to FIGS. 4 and 5, the system for surface-modifying a ceramic coating layer includes a furnace 310 configured to adjust an inner temperature by a heating means 320, a substrate (oxide part) 10 accommodated in the furnace 310 and having a ceramic coating layer 20, and a raw material 200 accommodated in a crucible 340 for surface modification of the ceramic coating layer. The raw material 200 is a material containing one or more anions selected from the group consisting of F⁻ and Cl⁻.

The furnace 310 may be a tube furnace or a muffle furnace, and may be configured to adjust an inner temperature by a heating means 320. The furnace 310 may be formed of an alumina (Al₂O₃) material, which is a chemically stable heat-resistant material and has a higher melting point than the thermal treatment temperature. It is preferable to mount a substrate 10 having a ceramic coating layer 20 on a support 330 provided higher than the bottom surface of the furnace 310 and smaller than the inner diameter of the furnace 310. The heating means 320 is configured to surround the furnace 310 and serves to heat the raw material 200 and the substrate 10 having the ceramic coating layer 20. The heating means 320 serves to increase the inner temperature of the furnace 310 to a desired temperature (e.g., 100 to 500° C.) and keep the inner temperature constant. The heating means 320 may use a method, such as resistance heating by a heating element or high frequency induction heating. The temperature in the furnace 310 may be constantly maintained by the heating means 320.

A gas inlet (not shown) through which a gas is input may be provided in the furnace 310. A gas such as a carrier gas or air may be input into the furnace 310 through the gas inlet.

A gas outlet (not shown) may be provided in the furnace 310, an exhaust system (not shown) such as a pump may be installed at the gas outlet, and the gas remaining in the furnace 310 may be discharged to the outside after thermal treatment.

A cooling cylinder (not shown) may be provided around the furnace 310, and may be water-cooled by cooling water (CW) flowing inside the cooling cylinder to prevent overheating of the inside of the furnace 310 and rapidly cool the inside of the furnace 310. A cooling water inlet (CWI) is connected to the cooling cylinder to provide cooling water, the provided cooling water is discharged through a cooling water outlet (CWO), and it is preferable to allow the cooling water to circulate in the cooling cylinder so that the furnace 310 can be cooled uniformly as a whole.

The substrate 10 having the ceramic coating layer 20 to be surface-modified is placed in the furnace 310, and the raw material 200 for surface modification is put into the crucible 340 and placed in the furnace 310 to be spaced apart from the substrate 10 having the ceramic coating layer 20 to be surface-modified. Heating temperatures for the position of the substrate 10 having the ceramic coating layer 20 and the position of the raw material 200 in the furnace 310 may be set differently from each other. The crucible 340 is preferably formed of alumina (Al₂O₃), graphite, carbon (carbon excluding graphite), tungsten or tantalum, which has high hardness and a high melting point, and when the crucible 340 formed of a material with a low melting point is used, the crucible material can act as an impurity in a subsequent thermal treatment process.

The substrate having the ceramic coating layer and the raw material are heated by the heating means 320, a carrier gas 350 is flowed to allow the vaporized raw material to move to the substrate 10 to be adsorbed to the surface of the ceramic coating layer 20 to surface-modify the ceramic coating layer 20. A heating temperature for the substrate 10 having the ceramic coating layer 20 and a heating temperature for the raw material 200 are set differently from each other. For example, the substrate 10 having the ceramic coating layer 20 is heated to 150 to 500° C., and the raw material 200 is heated to 100 to 450° C. It is preferable to set the heating temperature for the raw material lower than that of the substrate 10 having the ceramic coating layer 20. The heating is performed for 10 minutes to 48 hours, more preferably 1 to 24 hours, and most preferably 2 to 12 hours. The carrier gas may be an inert gas such as argon (Ar) or helium (He), or an unreactive gas such as nitrogen (N₂) gas. The carrier gas is preferably provided at a flow rate of 0.01 to 2.0 L/min, and more preferably 0.1 to 1.0 L/min. The carrier gas is provided to one end of the furnace 310 close to the side where the raw material 200 is placed to move to the other end of the furnace 310. The vaporized raw material takes advantage of the flow of the carrier gas and flows to the site at which the substrate is placed.

The vaporized raw material moves to the ceramic coating layer 20 to be surface-modified, a F⁻ anion element intrudes into the ceramic coating layer 20 and thus the surface of the ceramic coating layer is modified, and a surface layer (upper layer) in which the surface of the ceramic coating layer is surface-modified with a composition containing one or more anions selected from the group consisting of F⁻ and Cl⁻. The surface layer is a layer in which an oxide composition component is modified with a composition containing one or more anions selected from the group consisting of F⁻ and Cl⁻. The thickness of the surface-modified ceramic coating layer (the thickness of the lower layer and the surface layer) is the same as that of the ceramic coating layer before surface modification, or is larger due to volume expansion of the surface layer by surface modification.

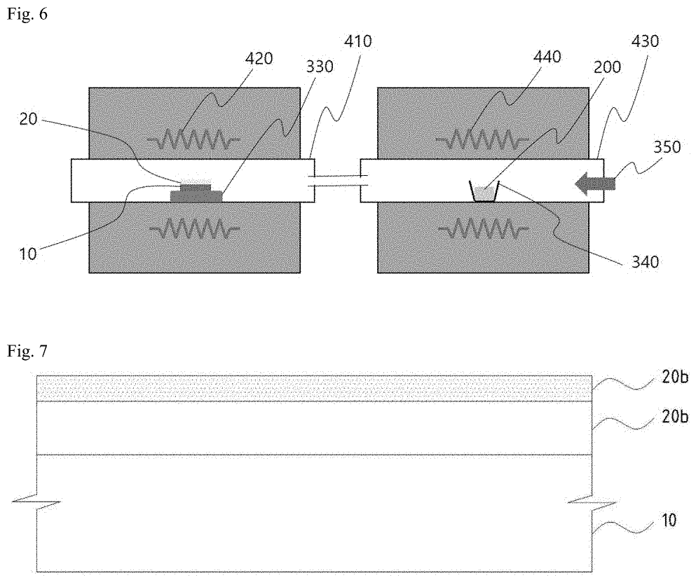

FIG. 6 shows a still another example of a system for surface-modifying a ceramic coating layer.

Referring to FIG. 6, the system for surface-modifying a ceramic coating layer includes a first furnace 410 configured to adjust an inner temperature by a first heating means 420, a substrate (oxide part) 10 having a ceramic coating layer 20 accommodated in the first furnace 410, a second furnace 430 configured to adjust an inner temperature by a second heating means 440, and a raw material 200 accommodated in the second furnace 430 for surface modifying the ceramic coating layer 20. The raw material 200 is a material containing one or more anions selected from the group consisting of F⁻ and Cl⁻. The first furnace 410 and the second furnace 430 are connected to each other.

The first furnace 410 may be a tube furnace or a muffle furnace, and may be configured to adjust an inner temperature by the first heating means 420. The second furnace 430 may be a tube furnace or a muffle furnace, and may be configured to adjust an inner temperature by the second heating means 440. The first and second furnaces may be formed of an alumina (Al₂O₃) material, which is a chemically stable heat-resistant material and has a higher melting point than the thermal treatment temperature. It is preferable to mount the substrate 10 having the ceramic coating layer 20 on a support 330 provided higher than the bottom surface of the first furnace 410 and smaller than the inner diameter of the first furnace 410. The first heating means 420 is configured to surround the first furnace 410 and serves to heat the substrate 10 having the ceramic coating layer 20. The first heating means 420 serves to increase the inner temperature of the first furnace 410 to a desired temperature (e.g., 100 to 500° C.) and keep the inner temperature constant. The first heating means 420 may use a method, such as resistance heating by a heating element or high frequency induction heating. The temperature in the first furnace 410 may be constantly maintained by the first heating means 420. The second heating means 440 is configured to surround the second furnace 430 and serves to heat the raw material.

The second heating means 440 serves to increases the inner temperature of the second furnace 430 to a desired temperature (e.g., 100 to 500° C.) and keep the inner temperature constant. The second heating means 440 may use a method, such as resistance heating by a heating element or high frequency induction heating. The temperature in the second furnace 430 may be constantly maintained by the second heating means 440.

A gas inlet (not shown) through which a gas is input may be provided in the second furnace 430. A gas such as a carrier gas or air may be input into the second furnace 430 through the gas inlet.

A gas outlet (not shown) may be provided in the first furnace 410, an exhaust system (not shown) such as a pump may be installed at the gas outlet, and the gas remaining in the first furnace 410 may be discharged to the outside after thermal treatment.

Cooling cylinders (not shown) may be provided around the first furnace 410 and the second furnace 430, respectively, and may be water-cooled by cooling water (CW) flowing inside the cooling cylinder to prevent overheating of the inside of the furnaces 410 and 430 and rapidly cool the insides thereof. A cooling water inlet (CWI) is connected to the cooling cylinder to provide cooling water, the provided cooling water is discharged through a cooling water outlet (CWO), and it is preferable to allow the cooling water to circulate in the cooling cylinder so that the first or second furnace 410 or 430 can be cooled uniformly as a whole.

The substrate 10 having the ceramic coating layer 20 to be surface-modified is placed in the first furnace 410. The raw material 200 is put into the crucible 340, and placed in the second furnace 430. The heating temperatures of the first furnace 410 and the second furnace 430 may be set differently from each other. The crucible 340 is preferably formed of alumina (Al₂O₃), graphite, carbon (carbon excluding graphite), tungsten or tantalum, which has high hardness and a high melting point, and when the crucible 340 formed of a material with a low melting point is used, the crucible material can act as an impurity in a subsequent thermal treatment process.

The substrate 10 having the ceramic coating layer 20 is heated by the first heating means 420, the raw material 200 is heated by the second heating means 440, a carrier gas 350 is flowed to the second furnace 430 to allow the vaporized raw material to be introduced into the first furnace 410, and the vaporized raw material introduced into the first furnace 410 is adsorbed to the surface of the ceramic coating layer 20 to surface-modify the ceramic coating layer 20. It is preferable that the heating temperature for the substrate 10 having the ceramic coating layer 20 and the heating temperature for the raw material 200 are set differently from each other. For example, the substrate 10 having the ceramic coating layer 20 is heated to 150 to 500° C., and the raw material 200 is heated to 100 to 450° C. It is preferable that the heating temperature for the raw material is set lower than that of the substrate 10 having the ceramic coating layer 20. The heating is performed for 10 minutes to 48 hours, more preferably 1 to 24 hours, and most preferably 2 to 12 hours. The carrier gas may be an inert gas such as argon (Ar) or helium (He), or an unreactive gas such as nitrogen (N₂) gas. The carrier gas is preferably provided at a flow rate of 0.01 to 2.0 L/min, and more preferably 0.1 to 1.0 L/min. The carrier gas is provided from one end of the second furnace 430 farthest apart from one end of the first furnace 410 and moves to the other end of the second furnace 430, and can move from the other end of the second furnace 430 to one end of the first furnace 410 via the other end of the first furnace 410. The vaporized raw material takes advantage of the flow of the carrier gas and moves to the site where the substrate is placed.

The vaporized raw material moves to the ceramic coating layer 20 to be surface-modified, a F⁻ anion element intrudes into the ceramic coating layer 20 and thus the surface of the ceramic coating layer is modified, and a surface layer (upper layer) in which the surface of the ceramic coating layer is surface-modified with a composition containing one or more anions selected from the group consisting of F⁻ and Cl⁻. The surface layer is a layer in which an oxide composition component is modified with a composition containing one or more anions selected from the group consisting of F⁻ and Cl⁻. The thickness of the surface-modified ceramic coating layer (the thickness of the lower layer and the surface layer) is the same as that of the ceramic coating layer before surface modification, or is larger due to volume expansion of the surface layer by surface modification.

As shown in FIG. 7, the manufactured plasma-resistant ceramic member is a ceramic member which includes a substrate 10 and a ceramic coating layer formed on the substrate 10, wherein the ceramic coating layer includes a lower layer 20a of an oxide composition formed on the substrate, and a surface layer (upper layer) 20b in which the oxide composition component constituting the surface of the ceramic coating layer is surface-modified with a composition containing one or more anions selected from the group consisting of F⁻ and Cl⁻.

Hereinafter, experimental examples according to the present invention are specifically presented, and the present invention is not limited to the following experimental examples.

### Experimental Example 1

A substrate on which a ceramic coating layer to be surface-modified as formed and a raw material for surface modification of the ceramic coating layer were put in a crucible. The substrate having the ceramic coating layer was a substrate formed of an alumina (Al₂O₃) material on which a Y₂O₃ coating layer was formed. The Y₂O₃ coating layer was formed by thermal spray coating, and the thickness of the ceramic coating layer was approximately 100 μm. As the raw material, a NH₄F powder was used. The substrate having the ceramic coating layer and the raw material were contained in the crucible at a volume ratio of 1:1. The crucible was formed of alumina (Al₂O₃) that has high hardness and a high melting point. As shown in FIG. 3, the crucible had a cover. The substrate having the Y₂O₃ coating layer was mounted on a support which was higher than the bottom surface of the crucible and smaller than the inner diameter thereof. The substrate having the Y₂O₃ coating layer, which was mounted on the support, was placed higher than the raw material. The substrate having the Y₂O₃ coating layer to be surface-modified was placed on the support on the lower surface of the crucible, and a raw material (NH₄F powder) containing an anion with high reactivity was contained on the bottom surface of the crucible.

The crucible having the substrate having the Y₂O₃ coating layer and the raw material was loaded into a chamber configured to adjust an inner temperature by a heating means. The chamber was formed of an alumina (Al₂O₃) material, which is a chemically stable heat-resistant material and has a higher melting point than the thermal treatment temperature. The chamber was air-tightly sealed so that there was no external gas inflow during surface modification.

The raw material (NH₄F powder) was heated by the heating means, and the vaporized raw material was adsorbed to the surface of the Y₂O₃ coating layer to modify the surface of the Y₂O₃ coating layer. The heating (thermal treatment) was performed at 170° C. for 4 hours. It was confirmed that an F⁻ anion element intrudes into the Y₂O₃ coating layer by the thermal treatment to modify the surface of the Y₂O₃ coating layer, and a YOₓF_{y} surface layer is formed on the surface of the Y₂O₃ coating layer. The thickness (the surface-modified thickness on the surface of the Y₂O₃ coating layer) of the surface layer formed on the surface of the Y₂O₃ coating layer was approximately 8 to 8.5 μm, and in terms of the anion composition of the surface layer, it was able to be confirmed that modification was made with a composition in which the atomic content of F is 6-fold higher than that of O.

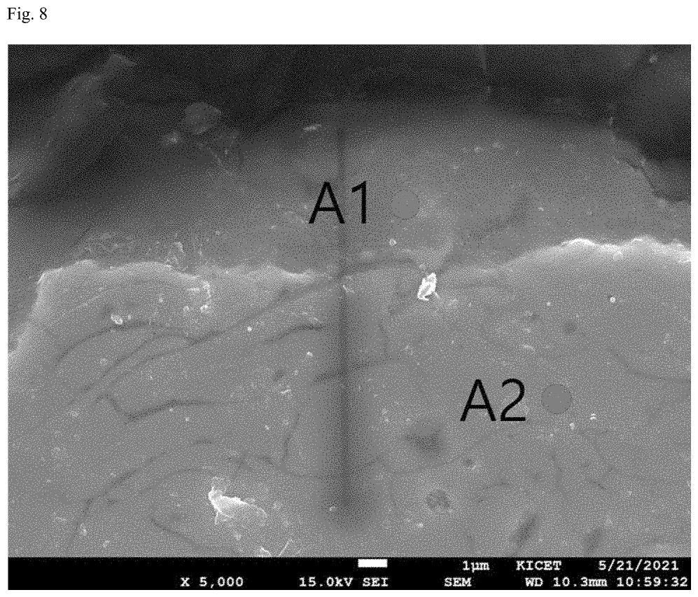

FIG. 8 is a scanning electron microscope (SEM) photograph showing the surface-modified cross-section of a Y₂O₃ coating layer according to Experimental Example 1. The content of a lower layer element (refer to ‘A2’ in FIG. 8) of the Y₂O₃ coating layer and the content of an element (refer to ‘A1’ in FIG. 8) of the surface-modified surface layer are shown in Table 1 below.

TABLE 1

| | Composition (at %) | |
|---|---|---|
| | A1 (surface-modified | A2 (lower layer of |
| Element | surface layer) | Y₂O₃ coating layer) |
| O | 10.4 | 47.5 |
| F | 64.1 | 10.0 |
| Y | 25.5 | 42.5 |
| Total | 100 | 100 |

Referring to Table 1, the lower layer is close to an oxide because the atomic ratio of 0 is higher than that of F, but the surface-modified surface layer is formed of an fluoride having a composition in which the atomic content of F is 6-fold or higher than that of O.

### Experimental Example 2

A substrate on which a ceramic coating layer (Y₂O₃ coating layer) was formed was prepared. The substrate having the ceramic coating layer was a substrate on which a Y₂O₃ coating layer was formed of an alumina (Al₂O₃) material. The Y₂O₃ coating layer was formed by electron beam deposition, which is widely used among physical vapor deposition (PVD) methods, and the thickness of the Y₂O₃ coating layer was approximately 4 μm.

As shown in FIG. 4, the substrate having the Y₂O₃ coating layer to be surface-modified was placed in the middle of a tube furnace. The substrate having the Y₂O₃ coating layer was mounted on a support higher than the bottom surface of the tube furnace and smaller than the diameter of the tube furnace. The tube furnace is configured to adjust an inner temperature by a heating means. The tube furnace is formed of an alumina (Al₂O₃) material, which is a chemically stable heat-resistant material and has a higher melting point than the thermal treatment temperature.

The raw material for surface modification was contained in a crucible, and placed in the tube furnace to be spaced apart from the substrate having the Y₂O₃ coating layer to be surface-modified. In the tube furnace, at the position of the substrate having the Y₂O₃ coating layer and the position of the raw material, heating temperatures may be set differently from each other. The crucible was formed of an alumina (Al₂O₃) material that has high hardness and a high melting point. The crucible had no cover. The raw material was a NH₄F powder containing an anion with high reactivity.

The raw material (NH₄F powder) was heated by the heating means, the vaporized raw material was adsorbed to the surface of the Y₂O₃ coating layer while flowing argon (Ar) gas to modify the surface of the Y₂O₃ coating layer. For the heating (thermal treatment), a heating temperature for the substrate having the Y₂O₃ coating layer and a heating temperature for the raw material were set differently from each other, the substrate having the Y₂O₃ coating layer was heated to 300° C., and the raw material was heated to 250° C. The heating was performed for 4 hours. The argon (Ar) gas was provided at a flow rate of 0.1 to 0.2 L/min. The argon (Ar) gas was provided from one end of the tube furnace close to the side where the raw material had been placed and moved to the other end of the tube furnace. The vaporized raw material took advantage of the flow of the argon gas and moved to the site where the substrate had been placed.

It was confirmed that an F⁻ anion element intrudes into the Y₂O₃ coating layer by the heating (thermal treatment) to modify the surface of the Y₂O₃ coating layer, and a YOₓF_{y} surface layer is formed on the surface of the Y₂O₃ coating layer.

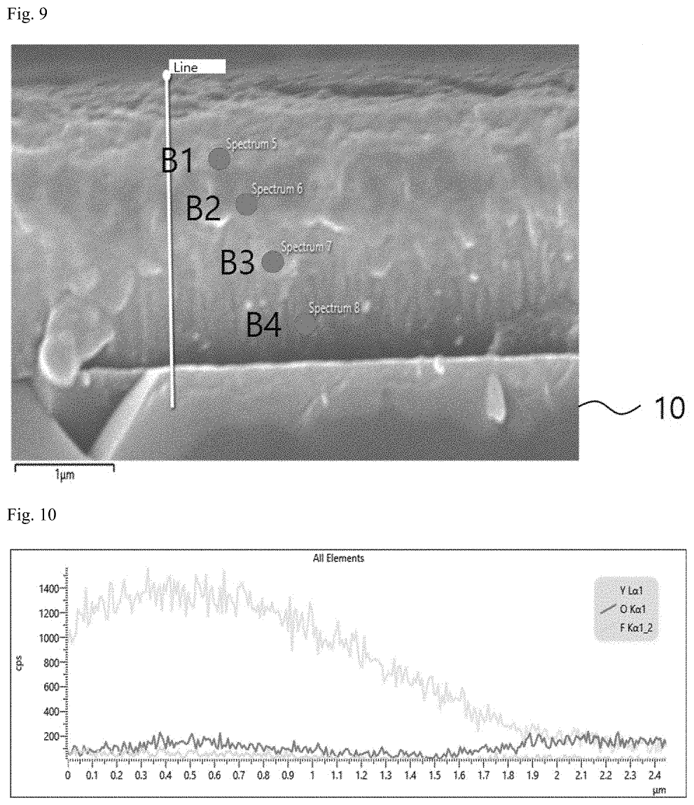

FIG. 9 is an SEM photograph showing the surface-modified cross-section of a Y₂O₃ coating layer according to Experimental Example 2, the element content for each cross-sectional position of the surface-modified Y₂O₃ coating layer (refer to ‘B1’ to ‘B4’ in FIG. 9) is shown in Table 2 below. FIG. 10 shows the energy dispersive X-ray spectroscopy (EDX) line profile of the surface-modified Y₂O₃ coating layer according to Experimental Example 2.

TABLE 2

| | Composition (at %) | | | |
|---|---|---|---|---|
| Element | B1 | B2 | B3 | B4 |
| O | 61.6 | 62.8 | 72.3 | 80.8 |
| F | 7.3 | 4.9 | 0 | 0 |
| Y | 31.1 | 32.3 | 27.7 | 19.2 |
| Total | 100 | 100 | 100 | 100 |

Referring to Table 2, the closer to the surface (from ‘B1’ to ‘B4’), it can be confirmed that the content of the oxygen element is lowered, and in the part close to the substrate 10 (refer to ‘B4’ in FIG. 9), it can be confirmed that fluorine (F) is not contained.

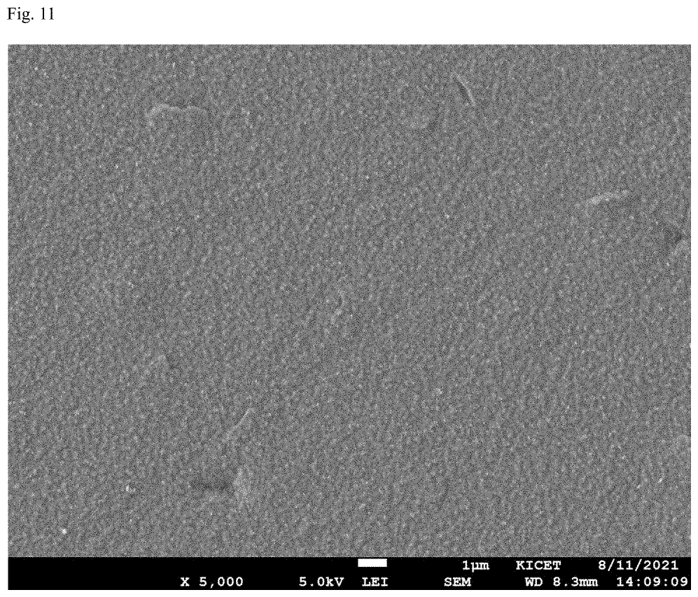

FIG. 11 is an SEM photograph showing the surface of the surface-modified Y₂O₃ coating layer according to Experimental Example 2. An element content of the surface of the surface-modified Y₂O₃ coating layer according to Experimental Example 2 is shown in Table 3 below.

TABLE 3

| Element | Composition (at %) |
|---|---|
| O | 53.5 |
| F | 12.5 |
| Y | 34.0 |
| [symbol] | 100 |

### Experimental Example 3

A substrate on which a ceramic coating layer (Y₂O₃ coating layer) was formed was prepared. The substrate having the ceramic coating layer was a substrate on which a Y₂O₃ coating layer was formed of a sapphire material. The Y₂O₃ coating layer was formed by electron beam deposition, which is widely used among physical vapor deposition (PVD) methods, and the thickness of the Y₂O₃ coating layer was approximately 4 μm.

As shown in FIG. 4, the substrate having the Y₂O₃ coating layer to be surface-modified was placed in the middle of a tube furnace. The substrate having the Y₂O₃ coating layer was mounted on a support higher than the bottom surface of the tube furnace and smaller than the diameter of the tube furnace. The tube furnace is configured to adjust an inner temperature by a heating means. The tube furnace is formed of an alumina (Al₂O₃) material, which is a heat-resistant material chemically stable and having a higher melting point than the thermal treatment temperature.

The raw material for surface modification was put into a crucible, and placed in the tube furnace to be spaced apart from the substrate having the Y₂O₃ coating layer to be surface-modified. At the position of the substrate having the Y₂O₃ coating layer and the position of the raw material in the tube furnace, heating temperatures can be set differently from each other. The crucible is formed of an alumina (Al₂O₃) material, which has high hardness and a high melting point. The crucible was a crucible without a cover. The raw material was a NH₄F powder containing an anion with high reactivity.

The raw material (NH₄F powder) was heated by the heating means, the vaporized raw material was adsorbed to the surface of the Y₂O₃ coating layer by flowing argon (Ar) gas to modify the surface of the Y₂O₃ coating layer. For the heating (thermal treatment), a heating temperature for the substrate having the Y₂O₃ coating layer and a heating temperature for the raw material were set differently from each other, the substrate having the Y₂O₃ coating layer was heated to 300° C., and the raw material was heated to 250° C. The heating was performed for 6 hours. The argon (Ar) gas was provided at a flow rate of 0.1 to 0.2 L/min. The argon (Ar) gas was provided from one end of the tube furnace close to the side where the raw material had been placed and moved to the other end of the tube furnace. The vaporized raw material took advantage of the flow of the argon gas and moved to the site where the substrate had been placed.

It was confirmed that an F⁻ anion element intrudes into the Y₂O₃ coating layer by heating (thermal treatment) to modify the surface of the Y₂O₃ coating layer, and a YOₓF_{y} surface layer is formed on the surface of the Y₂O₃ coating layer.

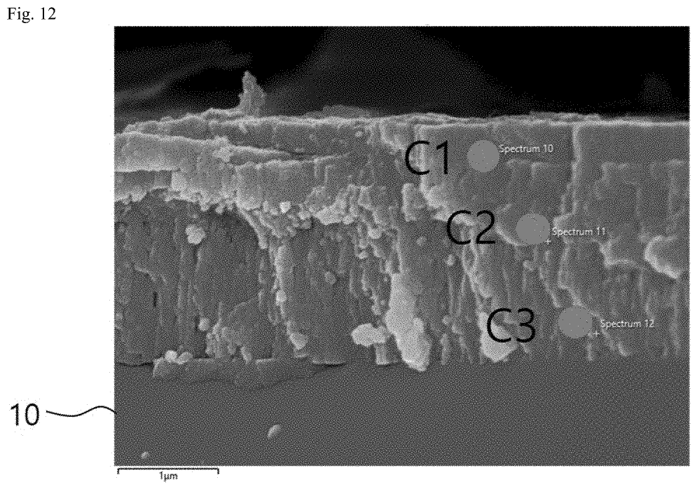

FIG. 12 is an SEM photograph showing the surface of the surface-modified Y₂O₃ coating layer according to Experimental Example 3, the element content for each cross-sectional position of the surface-modified Y₂O₃ coating layer (refer to ‘C1’ to ‘C3’ in FIG. 12) is shown in Table 4 below.

TABLE 4

| | Composition (at %) | | |
|---|---|---|---|
| Element | C1 | C2 | C3 |
| O | 44.8 | 56.8 | 65.5 |
| F | 18.9 | 6.1 | 4.8 |
| Y | 36.3 | 37.1 | 26.7 |
| Total | 100 | 100 | 100 |

Referring to Table 4, the closer to the surface (‘C1’ from ‘C3’ to ‘C1’), it can be confirmed that the content of the oxygen element is lowered and the fluorine (F) content increases, and in the part close to the substrate 10 (refer to ‘C3’ in FIG. 12), it can be confirmed that the fluorine (F) content is the lowest.

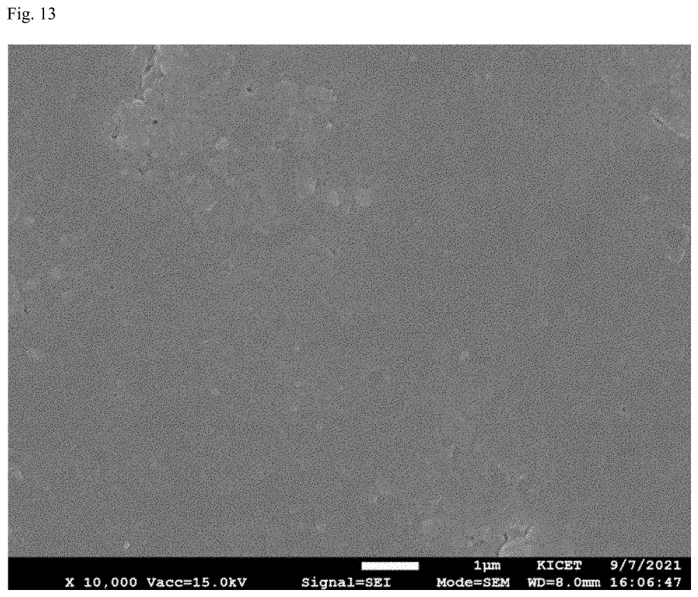

FIG. 13 is an SEM photograph showing the surface of the surface-modified Y₂O₃ coating layer according to Experimental Example 3. An element content of the surface of the surface-modified Y₂O₃ coating layer according to Experimental Example 3 is shown in Table 5 below.

TABLE 5

| Element | Composition (at %) |
|---|---|
| O | 49.3 |
| F | 18.9 |
| Y | 31.8 |
| [symbol] | 100 |

As described above, although preferred embodiments of the present invention have been described in detail, the present invention is not limited to the above embodiments, and various modifications are possible by those of ordinary skill in the art.

According to the present invention, plasma resistance, durability and etching process stability can be improved by surface-modifying the surface of a ceramic coating layer coated on a substrate with a composition containing one or more anions selected from the group consisting of F⁻ and Cl⁻ using raw materials containing F or Cl and a low-cost thermal treatment technique providing raw materials by vaporization. Plasma resistance and durability can be strengthened through surface modification of a ceramic oxide part applied to semiconductor chip production process equipment (etching, CVD coating, etc.). It is possible to improve the plasma resistance, durability and etching process stability of a ceramic substrate such as yttria (Y₂O₃), whose industrial application is actively progressing in recent years.

Conventionally, to obtain a composition containing F for improvement in plasma resistance, a process of mixing a F-containing raw material in a desired composition, a process of preparing a 10- to 50-μm spherical granular powder through spheroidization of the synthesized raw material, a process of thermally treating the spherical granular powder, and a process of coating the spherical powder using an expensive device such as a plasma sprayer had to be used. In this case, the conventional method not only includes a process of synthesizing and spheroidizing a solid raw material containing expensive F in advance, but also has a disadvantage in which coating is not performed with a desired composition due to volatilization or oxidation of F by high heat generated during plasma spraying. In addition, when the shape of a substrate serving as a base material for coating in the conventional method has a curved shape or an inner structure such as a hole, according to the conventional coating method, the moving distance of the molten raw material is changed by plasma spraying, and due to the volatilization of fluorine of the molten product during the movement, it is impossible to uniformly coat the entire curved surface of the substrate with a constant fluorine content. Another conventional coating method such as PVD, other than plasma spraying, also has similar limitations. According to the present invention, complicated process procedures including a coating raw material synthesis process, a spheroidization process, and a plasma spraying are not needed, and particularly, there is no need to separately configure the manufacturing and coating processes of the substrate to be a base for coating, and the surface can be changed with a composition containing F or Cl only through a simple surface modification process using the final product as a substrate regardless of a geometric shape. Particularly, when power of an electron beam is adjusted to adjust a deposition rate during the procedure of melting and depositing an evaporation source using the electron beam, it is possible to overcome the difficulty in constantly maintaining the contents of oxygen and fluorine of the deposited coating layer due to the fluctuated evaporation rates of oxygen and fluorine.

According to the present invention, the deterioration of the ceramic substrate can be suppressed even when exposed to an F- or Cl-based plasma process environment, and thus contamination caused by a semiconductor manufacturing process can be suppressed, the wafer production yield can be improved, and a post-processing cost for part recycling, such as a cleaning process, can be reduced.

In addition, according to the present invention, during an etching process using a fluorine-containing plasma such as a semiconductor wafer etching process, there is an advantage of preventing the consumption of fluorine in the plasma by the reaction of a chamber inner wall composed of Y₂O₃ coating with a fluorine radical or fluorine-containing ion in the plasma. Generally, by consuming certain amounts or more of fluorine radicals and fluorine-containing ions by the reaction with the chamber inner wall, the composition of the plasma is changed and it takes a lot of time to keep an etching rate constant, whereas the coating in the present invention, which is surface-modified by fluorine in advance, has the advantage of taking a short time to keep an etching rate constant.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

[Explanation of Reference Numerals]

| | |
|---|---|
| 10: | substrate |
| 20a: | lower layer |
| 20b: | surface layer (upper layer) |
| 100: | chamber |
| 110, 340: | crucible |
| 120, 330: | support |
| 130: | cover |
| 200: | raw material |
| 310: | furnace |
| 320: | heating means |
| 350: | carrier gas |
| 410: | first furnace |
| 420: | first heating means |
| 430: | second furnace |
| 440: | second heating means. |

What is claimed is:

1. A plasma-resistant ceramic member, comprising:
a substrate; and
a ceramic coating layer formed on the substrate,
wherein the ceramic coating layer comprises
a lower layer consisting of an oxide formed on the substrate; and
a surface layer in which an oxide composition component constituting the surface of the ceramic coating layer is surface-modified with a composition containing one or more anions selected from the group consisting of F⁻ and Cl⁻,
wherein the surface layer is a layer in which a raw material containing one or more anions selected from the group consisting of F⁻ and Cl⁻ is vaporized by heating and adsorbed to the surface of the ceramic coating layer, and thus modified with a composition containing one or more anions selected from the group consisting of F⁻ and Cl⁻.

2. The member of claim 1, wherein the lower layer consists of Y₂O₃, Y₃Al₅O₁₂, yttria-stabilized zirconia, or zirconia doped with one or more elements selected from rare earth elements, Ca and Mg.

3. The member of claim 1, wherein the surface layer has a thickness of 100 nm to 50 μm.

4. The member of claim 1, wherein the raw material comprises one or more solid materials selected from the group consisting of NH₄F, NH₅F₂, LiF, NaF, KF, MgF₂, CaF₂, AlF₃ and YF₃.

5. The member of claim 1, wherein the raw material comprises one or more solid materials selected from the group consisting of NH₄Cl, YCl₃, AlCl₃ and TaCl₃.

6. The member of claim 1, wherein the raw material is a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

7. The member of any one of claim 4, wherein a non-reactive solid diluent is further mixed with the raw material and heated together, and the amount of the raw material vaporized by heating is adjusted by the non-reactive solid diluent.

8. The member of claim 1, wherein the concentration of the vaporized raw material is controlled or an atmosphere for surface modification is controlled by inputting an inert carrier gas in a process of moving the vaporized raw material to the ceramic coating layer.

9. The member of claim 1, wherein the oxygen content of the modified surface layer is controlled by inputting air or oxygen (O₂) gas in the process of moving the vaporized raw material to the ceramic coating layer.

10. The member of claim 1, wherein the surface layer is formed by heating a ceramic coating layer to be surface-modified and a raw material containing one or more anions selected from the group consisting of F⁻ and Cl⁻, adsorbing the raw material vaporized by heating to the surface of the heated ceramic coating layer and thus modifying the surface of the ceramic coating layer with a composition including one or more anions selected from the group consisting of F⁻ and Cl⁻.

11. The member of claim 1, wherein the surface layer is formed by heating the raw material to a temperature of 100 to 500° C. to vaporize the same and adsorbing the resultant to the surface of the ceramic coating layer.

12. A method of manufacturing a plasma-resistant ceramic member, comprising:
(a) preparing a substrate on which a ceramic coating layer is formed of an oxide composition;
(b) heating and vaporizing a raw material containing one or more anions selected from the group consisting of F⁻ and Cl⁻; and
(c) forming a surface layer by adsorbing the vaporized raw material to the surface of the ceramic coating layer and modifying the surface of the ceramic coating layer,
wherein the surface layer is a layer in which an oxide composition component is modified with a composition comprising one or more anions selected from the group consisting of F⁻ and Cl⁻.

13. The method of claim 12, wherein the ceramic coating layer consists of Y₂O₃, Y₃AlO₁₂, yttria-stabilized zirconia, or zirconia doped with one or more elements selected from rare earth elements, Ca and Mg.

14. The method of claim 12, wherein the surface layer is formed to have a thickness of 100 nm to 50 μm.

15. The method of claim 12, wherein the raw material comprises one or more solid materials selected from the group consisting of NH₄F, NH₅F₂, LiF, NaF, KF, MgF₂, CaF₂, AlF₃ and YF₃.

16. The method of claim 12, wherein the raw material comprises one or more solid materials selected from the group consisting of NH₄Cl, YCl₃, AlCl₃ and TaCl₃.

17. The method of claim 12, wherein the raw material is a solid material in which one or more materials selected from the group consisting of NH₄F, NH₅F₂, LiF, NaF, KF, MgF₂, CaF₂, AlF₃ and YF₃ are mixed with one or more materials selected from the group consisting of NH₄Cl, YCl₃, AlCl₃ and TaCl₃.

18. The method of nay one of claim 15, wherein a non-reactive solid diluent is further mixed with the raw material and heated together, and the amount of the raw material vaporized by heating is adjusted by the non-reactive solid diluent.

19. The method of claim 12, wherein the concentration of the vaporized raw material is controlled or an atmosphere for surface modification is controlled by inputting an inert carrier gas in a process of moving the vaporized raw material to the ceramic coating layer.

20. The method of claim 12, wherein an oxygen content of the modified surface layer is controlled by inputting air or oxygen (O₂) gas in the process of moving the vaporized raw material to the ceramic coating layer.

21. The method of claim 12, wherein the surface layer is formed by modifying the surface of the ceramic coating surface with a composition including one or more anions selected from the group consisting of F⁻ and Cl⁻ by heating the ceramic coating layer to be surface-modified and the raw material containing one or more anions selected from the group consisting of F⁻ and Cl⁻ and adsorbing the raw material vaporized by heating to the surface of the ceramic coating layer.

22. The method of claim 12, wherein the surface layer is formed by heating the raw material to a temperature of 100 to 500° C. to vaporize the same and adsorbing the resultant to the surface of the ceramic coating layer.

23. The method of claim 12, wherein Step (b) comprises
(d) putting the substrate on which a ceramic coating layer to be surface-modified is formed and the raw material containing one or more anions selected from the group consisting of F⁻ and Cl⁻ into a crucible;
(e) loading the crucible in which the substrate having the ceramic coating layer and the raw material are contained into a chamber configured to adjust an inner temperature by a heating means; and
(f) heating and vaporizing the raw material using the heating means.

24. The method of claim 23, wherein Step (d) is to put the substrate having the ceramic coating layer and the raw material into the crucible to be placed separately from each other.

25. The method of claim 24, wherein the substrate having the ceramic coating layer is placed higher than the raw material.

26. The method of claim 24, wherein a support provided to be higher than the bottom surface of the crucible and smaller than the inner diameter thereof is provided in the crucible,
the raw material is placed on the bottom surface of the crucible, and
the substrate having the ceramic coating layer is mounted on the support to be placed higher than the raw material, so that the raw material and the substrate having the ceramic coating layer are spatially separated.

27. The method of claim 12, wherein Step (b) comprises
placing the substrate having the ceramic coating layer to be surface modified in a furnace;
putting the raw material for surface modification in the crucible, and placing the crucible in the furnace so that the raw material is spaced apart from the substrate having the ceramic coating layer to be surface-modified; and
heating and vaporizing the raw material using a heating means,
wherein, in the furnace, a heating temperature for the substrate having the ceramic coating layer and a heating temperature for the raw material are set differently from each other.

28. The method of claim 27, wherein the heating temperature for the raw material is set lower than that of the substrate having the ceramic coating layer.

29. The method of claim 27, wherein the substrate having the ceramic coating layer and the raw material are heated using the heating means, and a carrier gas is flowed to allow the vaporized raw material to move to the substrate to be adsorbed to the surface of the ceramic coating layer.

30. The method of claim 12, wherein Step (b) comprises
placing the substrate having the ceramic coating layer to be surface-modified in a first furnace;
putting a raw material for surface modification in a crucible and placing the crucible in a second furnace; and
heating and vaporizing the substrate having the ceramic coating layer using a first heating means and heating and vaporizing the raw material using a second heating means,
wherein a heating temperature for the substrate having the ceramic coating layer and a heating temperature for the raw material are set differently from each other.

31. The method of claim 30, wherein the heating temperature for the raw material is set lower than that of the substrate having the ceramic coating layer.

32. The method of claim 30, wherein the substrate having the ceramic coating layer is heated using the first heating means, the raw material is heated using the second heating means, a carrier gas is flowed to the second furnace to allow the vaporized raw material to be introduced into the first furnace, and the vaporized raw material introduced into the first furnace moves to the substrate to be adsorbed to the surface of the ceramic coating layer.
